(19) United States
(12) Patent Application Publication
(10) Pub. No.: US 2026/0150731 A1
(43) Pub. Date: May 28, 2026

(54) SEMICONDUCTOR PACKAGE

(71) Applicant: SAMSUNG ELECTRONICS CO., LTD., Suwon-si (KR)

(72) Inventors: Keunyoung LEE, Suwon-si (KR); Dongok KWAK, Suwon-si (KR)

(73) Assignee: SAMSUNG ELECTRONICS CO., LTD., Suwon-si (KR)

(21) Appl. No.: 19/287,032

(22) Filed: Jul. 31, 2025

(30) Foreign Application Priority Data
Nov. 26, 2024 (KR) 10-2024-0171123

(51) Int. Cl. H01L 23/538; H01L 23/00; H01L 25/18; H10B 80/00; H10D 80/30

(52) U.S. Cl. CPC H10W 70/65; H10B 80/00; H10D 80/30; H10W 70/611; H10W 90/00; H10W 72/884; H10W 90/20; H10W 90/24; H10W 90/724; H10W 90/732; H10W 90/734; H10W 90/752; H10W 90/754

(57) ABSTRACT

A semiconductor package includes a package substrate, a control chip, and a chip stack. A connection conductive pattern is on the top surface of the package substrate, spaced from the control chip. The package substrate has a first substrate pad, an extended interconnection line with first and second branch portions, and first and second interconnection lines. The control chip includes a mode selection pin and a chip connection terminal between the first substrate pad and the mode selection pin. The connection conductive pattern contacts the first branch portion and the first interconnection line but is spaced from the second branch portion and second interconnection line. A level of a top surface of the connection conductive pattern is lower than a level of a bottom surface of the control chip.

### CROSS-REFERENCE TO RELATED APPLICATIONS

This U.S. non-provisional patent application claims priority under 35 U.S.C. § 119 to Korean Patent Application No. 10-2024-0171123, filed on Nov. 26, 2024, in the Korean Intellectual Property Office, the entire contents of which are hereby incorporated by reference.

### BACKGROUND OF THE INVENTION

The present disclosure relates to a semiconductor package, and in particular, to a multi-chip package including a plurality of stacked chips.

A semiconductor package includes a semiconductor chip that is provided to be easily used as a part of an electronic product. In general, the semiconductor package includes a printed circuit board (PCB) and a semiconductor chip, which is mounted on the PCB and is electrically connected to the PCB using bonding wires or bumps. With development of the electronics industry, many studies are being conducted to improve the electrical and reliability characteristics of the semiconductor package and to reduce the size of the semiconductor package.

### SUMMARY

An embodiment of the present disclosure provides a semiconductor package, in which a control chip is mounted on a package substrate in a flip-chip bonding manner, and which is configured to allow for the mode selection of the control chip without changing the design of the package substrate.

According to an embodiment of the present disclosure, a semiconductor package may include a package substrate, a control chip and a chip stack on the package substrate, and a connection conductive pattern disposed on a top surface of the package substrate and spaced apart from the control chip in a horizontal direction. The package substrate may include a first substrate pad, an extended interconnection line connected to the first substrate pad, the extended interconnection line including a first branch portion and a second branch portion, a first interconnection line spaced apart from the first branch portion in the horizontal direction, and a second interconnection line spaced apart from the second branch portion in the horizontal direction. The control chip may include a mode selection pin, and a chip connection terminal disposed between the first substrate pad and the mode selection pin. The connection conductive pattern may be in contact with an end portion of the first branch portion and an end portion of the first interconnection line and may be spaced apart from the second branch portion and the second interconnection line. A level of a top surface of the connection conductive pattern may be lower than a level of a bottom surface of the control chip.

According to an embodiment of the present disclosure, a semiconductor package may include a package substrate, and a control chip and a chip stack on the package substrate. The package substrate may include a substrate pad, an extended interconnection line connected to the substrate pad, the extended interconnection line including a first branch portion and a second branch portion, a first interconnection line spaced apart from the first branch portion in a horizontal direction, and a second interconnection line spaced apart from the second branch portion in the horizontal direction. The control chip may include a mode selection pin, and a chip connection terminal disposed between the substrate pad and the mode selection pin. The semiconductor package may further include a connection conductive pattern, which is selectively disposed in one of a first region between the first branch portion and the first interconnection line or a second region between the second branch portion and the second interconnection line. The first interconnection line, the second interconnection line, the extended interconnection line, and the connection conductive pattern may be disposed on a same plane.

According to an embodiment of the present disclosure, a semiconductor package may include a package substrate, a solder resist layer on the package substrate, a control chip and a chip stack on the solder resist layer, and a molding member covering the control chip and the chip stack. The package substrate may include a substrate pad, an extended interconnection line connected to the substrate pad, the extended interconnection line including a first branch portion and a second branch portion, a first interconnection line spaced apart from the first branch portion in a horizontal direction, and a second interconnection line spaced apart from the second branch portion in the horizontal direction. The control chip may include a mode selection pin, and a chip connection terminal disposed between the substrate pad and the mode selection pin. The chip stack may include a plurality of memory chips stacked in a vertical direction, and connection structures electrically connecting the memory chips to the package substrate. The solder resist layer may cover a portion of the extended interconnection line, the first interconnection line, and the second interconnection line. The solder resist layer may include a first opening and a second opening. The first opening may expose an end portion of the first branch portion and an end portion of the first interconnection line, and the second opening may expose an end portion of the second branch portion and an end portion of the second interconnection line. The semiconductor package may further include a connection conductive pattern disposed in the first opening. The connection conductive pattern may be in contact with the end portion of the first branch portion and the end portion of the first interconnection line and may be spaced apart from the second branch portion and the second interconnection line. One of the first and second interconnection lines may be applied with a power voltage, and another one of the first and second interconnection lines may be applied with a ground voltage.

### BRIEF DESCRIPTION OF THE DRAWINGS

FIG. 1 is a block diagram illustrating a schematic structure of a semiconductor package according to an embodiment of the present disclosure.

FIG. 2 is a plan view illustrating a semiconductor package according to an embodiment of the present disclosure.

FIG. 3 is an enlarged sectional view illustrating a region ‘EV1’ of FIG. 2.

FIG. 4A is a sectional view illustrating a portion of FIG. 2, in which a connection conductive pattern is disposed.

FIG. 4B is an enlarged sectional view illustrating a region ‘EV2’ of FIG. 4A.

FIG. 5 is a sectional view illustrating a portion of FIG. 2, in which a connection conductive pattern is not disposed.

FIG. 6 is a plan view illustrating a semiconductor package according to an embodiment of the present disclosure.

FIG. 7 is a sectional view illustrating a portion of FIG. 6, in which a connection conductive pattern is disposed.

FIG. 8 is a plan view illustrating a semiconductor package according to an embodiment of the present disclosure.

FIG. 9 is a plan view illustrating a semiconductor package according to an embodiment of the present disclosure.

FIG. 10 is a sectional view illustrating a portion of FIG. 9, in which a connection conductive pattern is disposed.

FIGS. 11 and 12 are plan views illustrating a process of exposing an extended interconnection line, a first metal line, and a second metal line.

### DETAILED DESCRIPTION

Example embodiments of the present disclosure will now be described more fully with reference to the accompanying drawings, in which example embodiments are shown.

In the present specification, the expression “elements are connected” includes both the meaning that the elements are electrically connected to each other and the meaning that they are connected through direct contact.

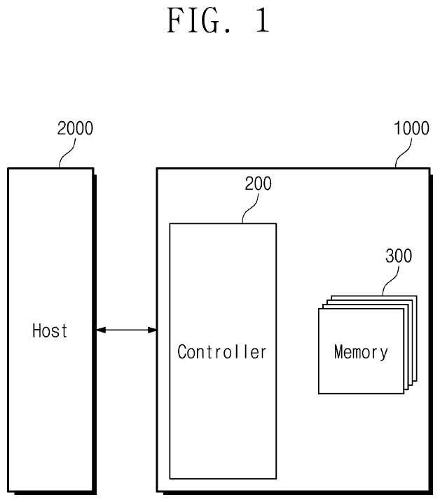

FIG. 1 is a block diagram illustrating a schematic structure of a semiconductor package according to an embodiment of the present disclosure.

Referring to FIG. 1, a semiconductor package may be a universal FLASH storage (UFS) package 1000. The UFS package 1000 may be configured to store or read data in response to read/write requests from a host 2000. The host 2000 may be an external electronic device. The UFS package 1000 may include a controller 200 and a memory device 300. The controller 200 may be configured to exchange signals with the host 2000. Here, the signals between the controller 200 and the host 2000 may include command, address, and/or data. The controller 200 may write or read data in or from a corresponding one of the memory devices 300 in response to the command from the host 2000. The memory device 300 may be a nonvolatile memory device. In an embodiment, a plurality of memory devices 300 may be provided. The memory devices 300 may be a NAND FLASH memory device (hereinafter, NAND) with a large capacity and a high speed. Alternatively, the memory devices 300 may be a phase change random access memory (PRAM) device, a magnetic random access memory (MRAM) device, a resistive random access memory (ReRAM) device, a ferromagnetic random access memory (FRAM) device, or a NOR FLASH memory device.

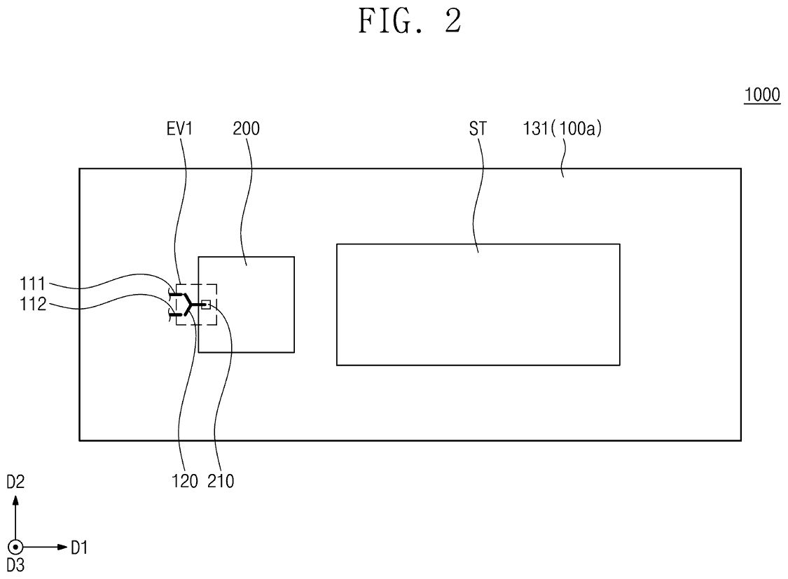

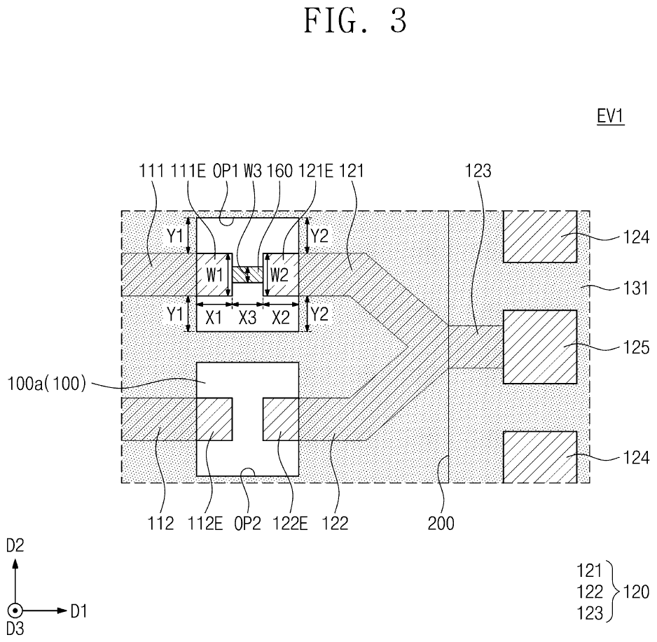

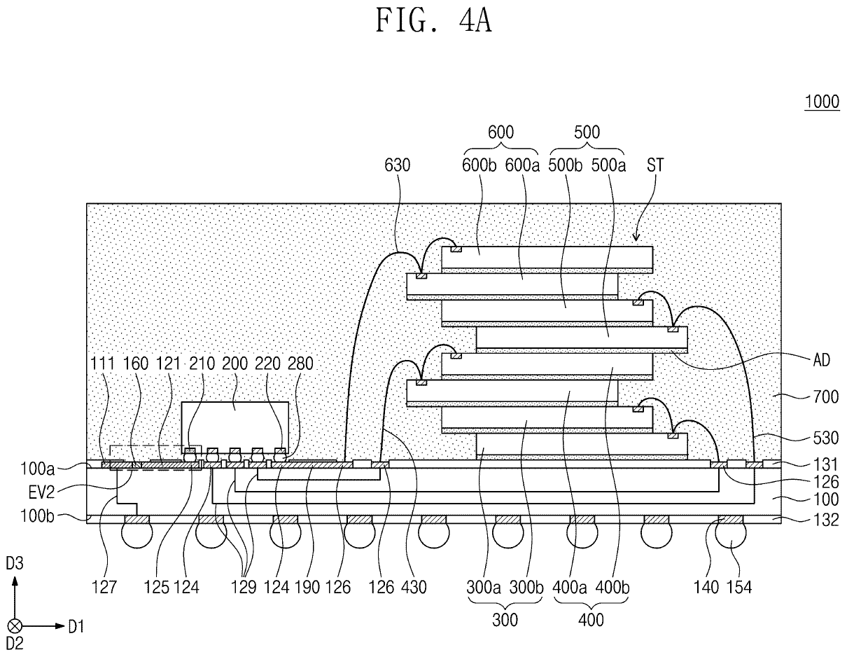

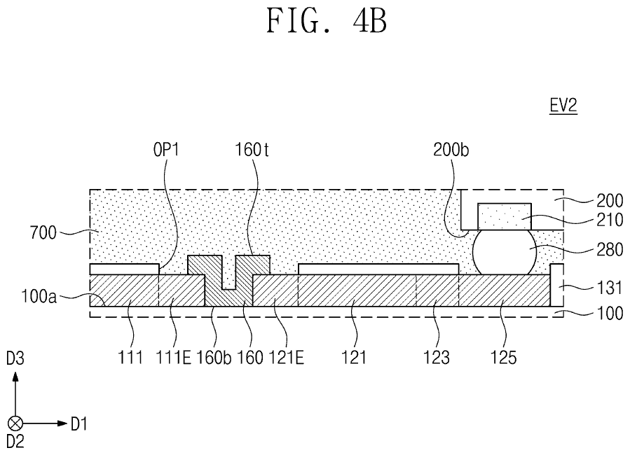

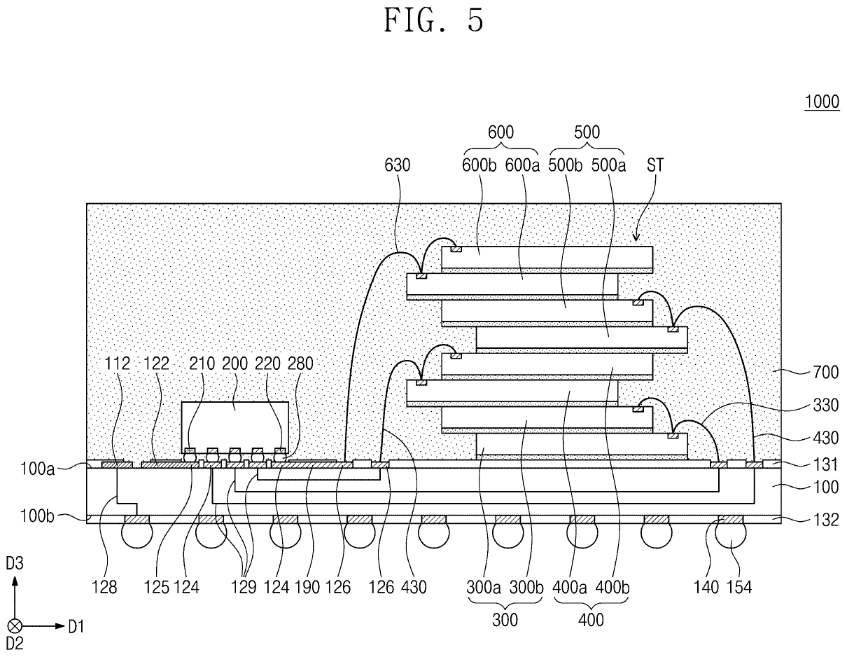

FIG. 2 is a plan view illustrating a semiconductor package according to an embodiment of the present disclosure. FIG. 3 is an enlarged sectional view illustrating a region ‘EV1’ of FIG. 2. FIG. 4A is a sectional view illustrating a portion of FIG. 2, in which a connection conductive pattern is disposed. FIG. 4B is an enlarged sectional view illustrating a region ‘EV2’ of FIG. 4A. FIG. 5 is a sectional view illustrating a portion of FIG. 2, in which a connection conductive pattern is not disposed.

Referring to FIGS. 2, 3, 4A, 4B, and 5, a semiconductor package 1000 may include a package substrate 100, first and second solder resist layers 131 and 132, a connection conductive pattern 160, a control chip 200, a chip stack ST, and a mold layer 700.

In an embodiment, the semiconductor package 1000 may be a multi-chip package (MCP) including semiconductor chips of different kinds. The semiconductor package 1000 may be a system-in-package (SIP) structure that is provided in a single package, in which a plurality of semiconductor chips are stacked or arranged, and has an independent function.

The package substrate 100 may be, for example, a printed circuit board (PCB). The package substrate 100 may include a first surface 100a and a second surface 100b, which are opposite to each other. The first surface 100a may mean a top surface of the package substrate 100, and the second surface 100b may mean a bottom surface of the package substrate 100. In the present specification, a first direction D1 may be a direction that is parallel to the first surface 100a of the package substrate 100, a second direction D2 may be a direction that is parallel to the first surface 100a of the package substrate 100 and is not parallel to the first direction D1, and a third direction D3 may be a direction that is perpendicular to a top surface 100a of the package substrate 100. In one embodiment, the first direction D1 and the second direction D2 may be horizontal directions intersecting each other, and the third direction D3 may be a vertical direction. The package substrate 100 may include a plurality of insulating layers and interconnection structures, which are disposed in the insulating layers. For example, the insulating layers may be formed of or include a composite material that is formed of glass fiber and epoxy resin. The interconnection structure may include interconnection lines, which are placed at different layers, and vias, which are provided to connect the interconnection lines to each other. In an embodiment, the interconnection structure may be formed of or include copper or aluminum.

The interconnection lines may include interconnection lines disposed on the first surface 100a and interconnection lines disposed on the second surface 100b. The interconnection structure may include a first sub-interconnection structure 127 (e.g., see FIG. 4A), a second sub-interconnection structure 128 (e.g., see FIG. 4B), and a third sub-interconnection structure 129, each of which includes interconnection lines disposed between the first surface 100a and the second surface 100b and vias provided to connect the interconnection lines to each other. The interconnection lines disposed on the first surface 100a may include a first interconnection line 111, a second interconnection line 112, a third interconnection line 190, an extended interconnection line 120, a first substrate pad 125, a second substrate pad 124, and a third substrate pad 126. The interconnection lines disposed on the second surface 100b may include lower substrate pads 140. Outer connection terminals 151, 152, and 154 may be disposed on the lower substrate pads 140.

The first solder resist layer 131 may be disposed on the first surface 100a of the package substrate 100. The first solder resist layer 131 may be provided to cover a portion of the first interconnection line 111, the second interconnection line 112, and the extended interconnection line 120 and to expose a portion of them. The first solder resist layer 131 may be provided to expose the first substrate pad 125, the second substrate pad 124, and the third substrate pad 126.

The second solder resist layer 132 may be disposed on the second surface 100b of the package substrate 100. The first and second solder resist layers 131 and 132 may be formed of or include, for example, an epoxy-based insulating resin. The second solder resist layer 132 may be provided to expose bottom surfaces of the lower substrate pads 140.

The extended interconnection line 120 may include an extended portion 123, a first branch portion 121, and a second branch portion 122. The extended portion 123 may be a portion that is extended from the first substrate pad 125 in the first direction D1. Each of the first and second branch portions 121 and 122 may be a portion, which is extended from the extended portion 123 and has a branch shape. The extended interconnection line 120 may have a “Y” shape, when viewed in a plan view. The first and second branch portions 121 and 122 may be spaced apart from each other in the second direction D2. The first and second branch portions 121 and 122 may not be disposed below a bottom surface of the control chip 200. That is, the first and second branch portions 121 and 122 may be placed outside the control chip 200, when viewed in a plan view.

An end portion 111E of the first interconnection line 111 may be disposed to be adjacent to but spaced apart from an end portion 121E of the first branch portion 121 in the first direction D1. An end portion 112E of the second interconnection line 112 may be disposed to be adjacent to but spaced apart from an end portion 122E of the second branch portion 122 in the first direction D1.

The first solder resist layer 131 may include a first opening OP1 and a second opening OP2. The first opening OP1 may be provided to expose the end portion 111E of the first interconnection line 111, the end portion 121E of the first branch portion 121, and a first region therebetween. The second opening OP2 may be provided to expose the end portion 112E of the second interconnection line 112, the end portion 122E of the second branch portion 122, and a second region therebetween.

Each of the end portions 111E and 112E of the first and second interconnection lines 111 and 112 may have a first width W1 in the second direction D2. Each of the end portions 111E and 11E of the first and second interconnection lines 111 and 112 may have a first exposed length X1 in the first direction D1. Each of the end portions 121E and 122E of the first and second branch portions 121 and 122 may have a second width W2 in the second direction D2. Each of the end portions 121E and 122E of the first and second branch portions 121 and 122 may have a second exposed length X2 in the first direction D1. For example, the first width W1 and the second width W2 may range from 7 μm to 30 μm. The first exposed length X1 and the second exposed length X2 may be larger than or equal to 15 μm. A distance Y1 from a side surface of the end portion 111E of the first interconnection line 111 to an inner side surface of the first opening OP1 in the second direction D2 and a distance Y2 from a side surface of the end portion 111E of the first branch portion 121 to an inner side surface of the first opening OP1 in the second direction D2 may be larger than or equal to 15 μm. A distance from a side surface of the end portion 112E of the second interconnection line 112 to an inner side surface of the second opening OP2 in the second direction D2 and a distance from a side surface of the end portion 122E of the second branch portion 122 to the inner side surface of the second opening OP2 in the second direction D2 may be larger than or equal to 15 μm.

A first distance X3 between the end portion 111E of the first interconnection line 111 and the end portion 121E of the first branch portion 121 may correspond to a width of the first region. A second distance between the end portion 112E of the second interconnection line 112 and the end portion 122E of the second branch portion 122 may correspond to a width of the second region. The first distance X3 and the second distance may be larger than or equal to 7 μm. The first distance X3 and the second distance may be smaller than the first exposed length X1 and the second exposed length X2.

The connection conductive pattern 160 may be selectively interposed between the end portion 111E of the first interconnection line 111 and the end portion 121E of the first branch portion 121 or between the end portion 112E of the second interconnection line 112 and the end portion 122E of the second branch portion 122. The connection conductive pattern 160 may be spaced apart from the control chip 200 in the first direction D1 and/or the second direction D2.

The connection conductive pattern 160 may have a third width W3 in the second direction D2. The third width W3 may be smaller than the first width W1 and the second width W2. In an embodiment, the third width W3 may be equal to or larger than the first width W1 and the second width W2.

As one exemplary measurement method of the aforementioned distances, lengths, or widths, a “distance” between two targeted surfaces may mean an average distance, a maximum distance, or a minimum distance among distances between the two surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

The connection conductive pattern 160 may include a metallic material different from the interconnection structure. For example, the first interconnection line 111, the second interconnection line 112, and the extended interconnection line 120 may be formed of or include copper, and the connection conductive pattern 160 may be formed of or include silver. The connection conductive pattern 160 may not be bonding wires. In an embodiment, the connection conductive pattern 160 may include the same metallic material as the interconnection structure. As shown in FIG. 4B, a bottom surface 160b of the connection conductive pattern 160 may be in contact with the top surface 100a of the package substrate 100, the side surface of the end portion 111E of the first interconnection line 111, and the side surface of the end portion 121E of the first branch portion 121 and may not be in contact with the second interconnection line 112 and the second branch portion 122. Alternatively. The bottom surface 160b of the connection conductive pattern 160 may be in contact with the top surface of the package substrate 100, the side surface of the second interconnection line 112, and the side surface of the second branch portion 122 and may not be in contact with the first interconnection line 111 and the first branch portion 121.

The first substrate pad 125 may be overlapped with a first pin 210 of the control chip 200 in the third direction D3 and may be connected to the first pin 210 through a chip connection terminal 280. The second substrate pad 124 may be overlapped with a second pin 220 of the control chip 200, which will be described below, in the third direction D3 and may be connected to the second pin 220 through the chip connection terminal 280. The second substrate pads 124 may be spaced apart from the first substrate pads 125 in the first direction D1 and/or the second direction D2. The third substrate pad 126 may be connected to metal connection lines 330, 430, 530, and 630, which will be described below. The first and second branch portions 121 and 122 may not be overlapped with the control chip 200 in the third direction D3.

As shown in FIG. 4A, a power voltage may be applied to the first interconnection line 111 through the first sub-interconnection structure 127. As shown in FIG. 4B, a ground voltage may be applied to the second interconnection line 112 through the second sub-interconnection structure 128. Depending on whether the connection conductive pattern 160 is connected to the first interconnection line 111 or the second interconnection line 112, the kind of the voltage applied to the first substrate pad 125 may be determined. The third sub-interconnection structure 129 may connect the second substrate pad 124 to the third substrate pad 126. The third interconnection line 190 may connect the second substrate pad 124 to the third substrate pad 126. In an embodiment, the third interconnection line 190 may be omitted.

The control chip 200 and the chip stack ST may be disposed on the package substrate 100. In an embodiment, the control chip 200 may be the controller described with reference to FIG. 1.

The control chip 200 may include a plurality of chip pads 210 and 220 disposed on a bottom surface 200b thereof. The bottom surface 200b of the control chip 200 may be an active surface. In the present specification, the chip pad may be referred to as a pin. The pins 210 and 220 may include first pins 210 and second pins 220. The first pins 210 may be mode selection pins. The second pins 220 may be a power supply pin and a signal pin. The mode selection pin 210 may be used to perform a mode selection of selecting one of various modes, based on a voltage applied from the outside. In an embodiment, the mode selection may mean recognizing a different number of channels of the memory chips 300 included in the chip stack ST, depending on the mode. In another embodiment, the mode selection may mean a ADDR way of addressing the memory chips 300 of the chip stack ST to activate each of the memory chips 300 or a chip-enable reduction (CER) way of activating all of the memory chips 300 without assigning an address, depending on the mode. In an embodiment, a plurality of first pins 210 may be provided and may be configured to have respective modes and functions different from each other. The power supply pin may be used to supply an electric power to the control chip 200, and the signal pin may be used as a data pin for sending or receiving signals. The first pins 210 and the second pins 220 may be electrically connected to the package substrate 100 through the chip connection terminals 280. The chip connection terminals 280 may be respectively interposed between the first pin 210 and the first substrate pad 125 and between the second pin 220 and the second substrate pad 124. The control chip 200 may be mounted on the package substrate 100 in a flip chip shape. The first and second pins 210 and 220 may include a metallic material. Each of the chip connection terminals 280 may include at least one of solder, pillar, and bump.

The chip stack ST may be provided on the top surface 100a of the package substrate 100. The chip stack ST may be spaced apart from the control chip 200 in the first or second direction D1 or D2. The chip stack ST may include the first to fourth memory chips 300, 400, 500, and 600, which are sequentially stacked on the top surface 100a of the package substrate 100. FIGS. 4A and 4B illustrate an example, in which the number of the chips included in the first to fourth memory chips 300, 400, 500, and 600 is 8, but the present disclosure is not limited to the specific number of the chips. Each of the first to fourth memory chips 300, 400, 500, and 600 may include a nonvolatile memory device (e.g., a NAND FLASH memory device). First memory chips 300a and 300b may be memory chips of the same kind. Similarly, each of the groups, which are respectively composed of second memory chips 400a and 400b, third memory chips 500a and 500b, and fourth memory chips 600a and 600b, may include memory chips of the same kind. The first memory chips 300a and 300b may be connected to each other using connection structures, such as bonding wires, and may share the same channel. Similar to the first memory chips 300a and 300b, each of the groups, which are respectively composed of the second memory chips 400a and 400b, the third memory chips 500a and 500b, and the fourth memory chips 600a and 600b, may be connected to each other using connection structures, such as bonding wires, and may share the same channel. The first memory chips 300a and 300b may be sequentially stacked on the package substrate 100 using adhesive layers AD. The second memory chips 400a and 400b, the third memory chips 500a and 500b, and the fourth memory chips 600a and 600b may be sequentially attached to the first memory chips 300a and 300b using the adhesive layers AD. In detail, the first memory chips 300a and 300b and the lowermost second memory chip 400a may be stacked in a cascade structure. The second memory chips 400a and 400b and the lowermost third memory chip 500a may be stacked in a cascade structure. The third memory chips 500a and 500b and the lowermost fourth memory chip 600a may be stacked in a cascade structure. The first to fourth memory chips 300, 400, 500, and 600 in the chip stack ST may be alternately disposed a direction toward the control chip 200 or a direction away from the control chip 200 and may be stacked in a cascade structure. Each of the first to fourth memory chips 300, 400, 500, and 600 may be electrically connected to each of the third substrate pads 126 by each of the first to fourth metal connection lines 330, 430, 530, and 630. In an embodiment, each of the first to fourth metal connection lines 330, 430, 530, and 630 may include a bonding wire. The first to fourth metal connection lines 330, 430, 530, and 630 may not be in contact with the extended interconnection line 120, the first interconnection line 111, and the second interconnection line 112.

The first to fourth metal connection lines 330, 430, 530, and 630, which are connected to the third substrate pads 126, may determine the number of channels in the semiconductor package 1000. In the case where, as shown in FIG. 3, four metal connection lines are connected to the third substrate pads 126, the number of channels may be four. However, the present disclosure is not limited to this example. For example, the number of the metal connection lines connected to the third substrate pads 126 may be changed, and in this case, the number of channels in the semiconductor package 1000 may be changed.

The mold layer or molding member 700 may cover the package substrate 100, the control chip 200, and the chip stack ST. The mold layer 700 may include an insulating material. The mold layer 700 may include, for example, an epoxy mold compound (EMC).

As shown in FIG. 4B, the mold layer 700 may not be interposed between the top surface 100a of the package substrate 100 and the bottom surface 160b of the connection conductive pattern 160. A level of a top surface 160t of the connection conductive pattern 160 may be lower than a level of the bottom surface 200b of the control chip 200. The bottom surface 160b of the connection conductive pattern 160 may be in contact with the insulating layer of the package substrate 100. The first interconnection line 111, the second interconnection line 112, the extended interconnection line 120, and the connection conductive pattern 160 may be disposed on the same plane (e.g., 100a).

According to an embodiment of the present disclosure, the connection conductive pattern 160 may be formed separately from the package substrate 100. Depending on the position of the connection conductive pattern 160, a voltage, which is applied to the extended interconnection line 120 connected to the connection conductive pattern 160, may be determined as a ground voltage or a power voltage. The determined voltage may be transmitted to the first pin 210 of the control chip 200. The control chip 200 may select the mode by recognizing the ground or power voltage applied to the first pin 210.

In the ADDR way, as the number of the memory chips increases, a second pin connected to the memory chips may be additionally needed in the control chip 200, and this may increase the size of the control chip 200. In addition, the third sub-interconnection structure 129 of the package substrate 100 may be additionally needed, and thus, the size of the package substrate 100 may be increased.

According to an embodiment of the present disclosure, by using the connection conductive pattern 160, the mode selection may be possible in a single package substrate 100, regardless of the number of the memory chips. Accordingly, depending on the number of the memory chips, it may be unnecessary to separately fabricate the package substrate 100. This may make it possible to reduce the process cost of the semiconductor package 1000. In addition, the connection conductive pattern 160 may be formed by a direct printing method (e.g., an inkjet printing method) to be described below. If the connection conductive pattern 160 is connected the first interconnection line 111 or the second interconnection line 112 using a bonding wire, it may be necessary to meet the requirements on minimum vertical width and minimum horizontal width for the bonding wires. By contrast, according to an embodiment of the present disclosure, since the connection conductive pattern is used, it may be possible to connect the connection conductive pattern 160 to the first interconnection line 111 or the second interconnection line 112 within a vertical width and a horizontal width that are smaller compared to the case of using the bonding wires. As a result, compared to the case of using the bonding wires, a package substrate with a smaller area may be used, and even when the same area is used, there may be an extra area where the third sub-interconnection structure 129 or the third interconnection line 190 can be additionally disposed.

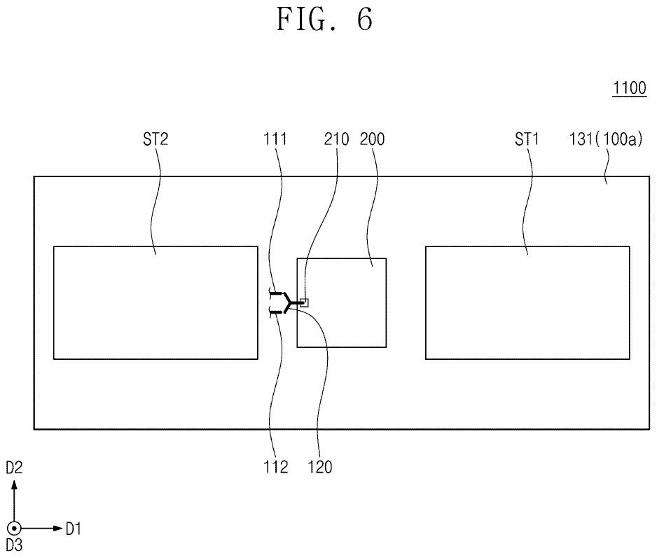

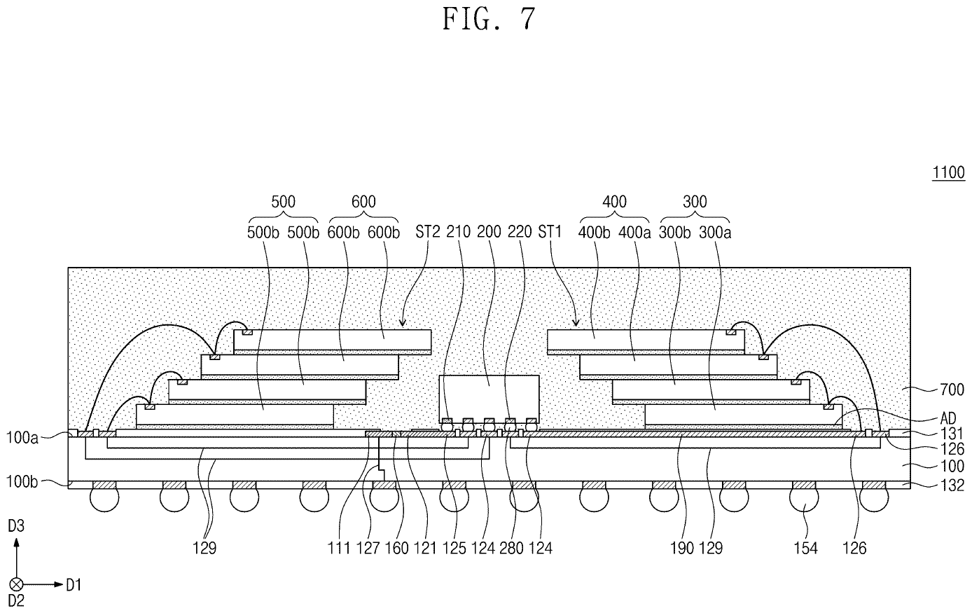

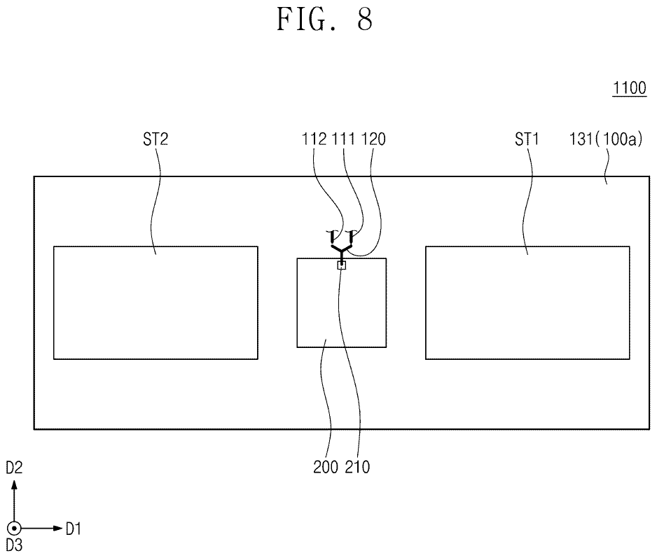

FIG. 6 is a plan view illustrating a semiconductor package according to an embodiment of the present disclosure. FIG. 7 is a sectional view illustrating a portion of FIG. 6, in which a connection conductive pattern is disposed. FIG. 8 is a plan view illustrating a semiconductor package according to an embodiment of the present disclosure. An element, except for those described below, may be identified by the same reference number without repeating an overlapping description.

Referring to FIGS. 6 and 7, a semiconductor package 1100 may include a first chip stack ST1 and a second chip stack ST2. The first chip stack ST1 and the second chip stack ST2 may be spaced apart from each other in the first direction D1, with the control chip 200 interposed therebetween.

The first chip stack ST1 may include the first and second memory chips 300 and 400, which are sequentially stacked on the top surface 100a of the package substrate 100. The second chip stack ST2 may include the third and fourth memory chips 500 and 600, which are sequentially stacked on the top surface 100a of the package substrate 100. The first memory chips 300a and 300b and the second memory chips 400a and 400b may be stacked to form a cascade structure in a direction toward the control chip 200. The third memory chips 500a and 500b and the fourth memory chips 600a and 600b may be stacked to form a cascade structure in a direction toward the control chip 200.

FIG. 6 illustrates an example, in which the first and second interconnection lines 111 and 112 and the extended interconnection line 120 are disposed between the first chip stack ST1 and the second chip stack ST2.

Alternatively, as shown in FIG. 8, the first and second interconnection lines 111 and 112 and the extended interconnection line 120 may be disposed in a region that is other than a region between the first chip stack ST1 and the second chip stack ST2.

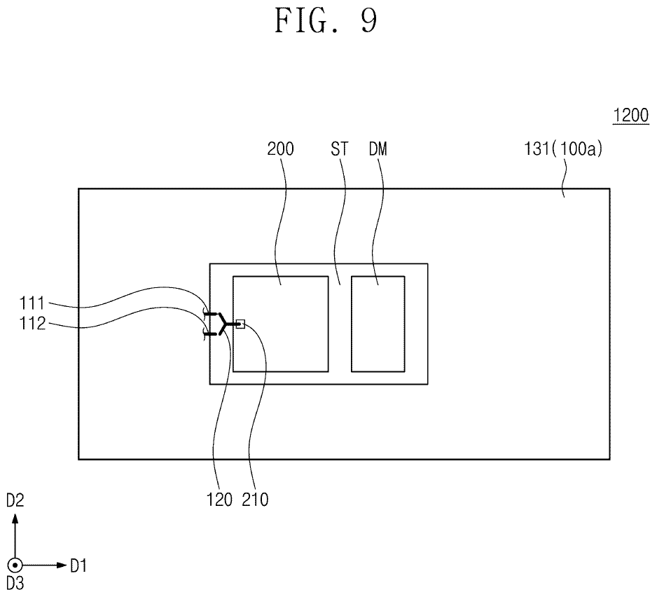

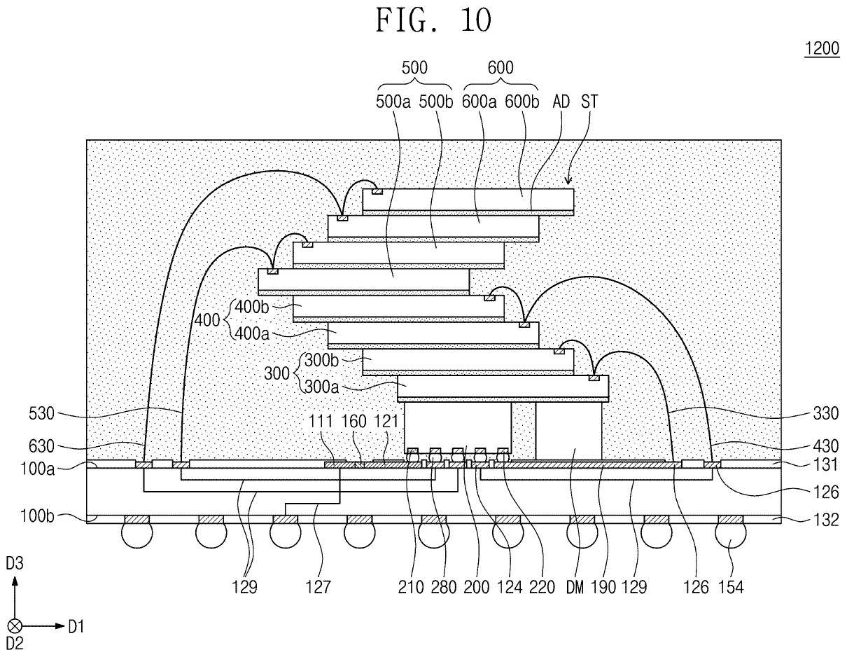

FIG. 9 is a plan view illustrating a semiconductor package according to an embodiment of the present disclosure. FIG. 10 is a sectional view illustrating a portion of FIG. 9, in which a connection conductive pattern is disposed. An element, except for those described below, may be identified by the same reference number without repeating an overlapping description.

Referring to FIGS. 9 and 10, the chip stack ST may be placed on the control chip 200. A semiconductor package 1200 may further include a supporting structure DM. The supporting structure DM may be a dummy structure. For example, the supporting structure DM may be a silicon dummy die. In an embodiment, the supporting structure DM may be an additional semiconductor chip, which has a function different from the control chip 200. A top surface of the control chip 200 and a top surface of the supporting structure DM may be connected to the chip stack ST through an adhesive layer AD disposed on a bottom surface of a first semiconductor chip 300a. The first and second interconnection lines 111 and 112 and the extended interconnection line 120 may be overlapped with the chip stack ST in the third direction D3.

Since the chip stack ST is vertically disposed on the control chip 200, it may be possible to reduce a required area of the package substrate 100, compared to the case that the chip stack ST is disposed next to the control chip 200 in a horizontal direction.

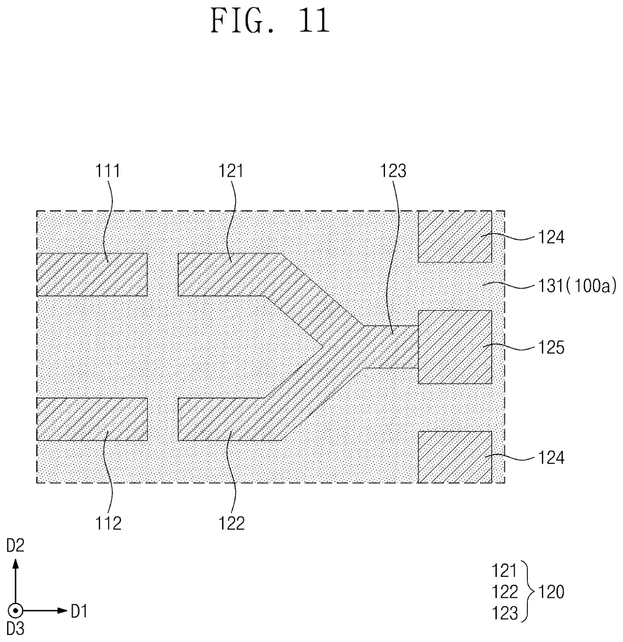

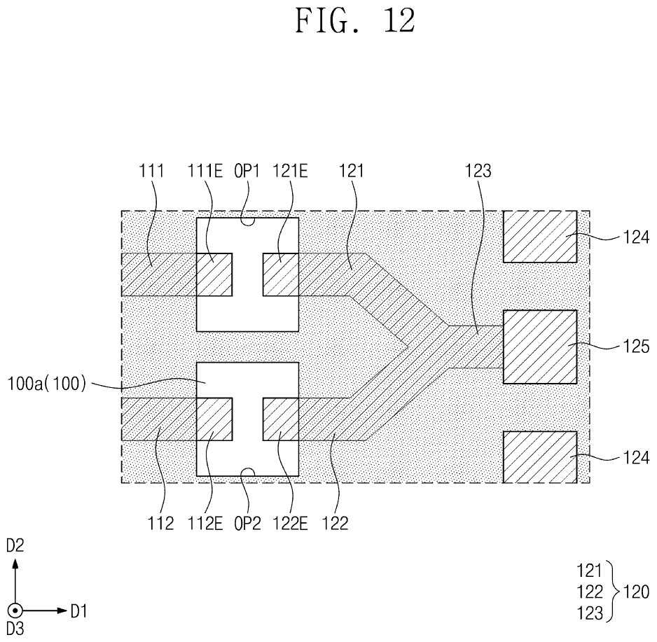

FIGS. 11 and 12 are plan views illustrating a process of exposing an extended interconnection line, a first metal line, and a second metal line. FIG. 3 is a plan view illustrating a process of forming a connection conductive pattern.

Referring to FIG. 11, the first solder resist layer 131 may be formed on the first surface 100a of the package substrate 100. The first solder resist layer 131 may cover the first and second interconnection lines 111 and 112, the extended interconnection line 120, and first to third substrate pads 125, 124, and 126.

Referring to FIG. 12, a photolithography process may be performed to form the first opening OP1, which exposes the end portion 111E of the first interconnection line 111, the end portion 121E of the first branch portion 121, and the first region therebetween, and the second opening OP2, which exposes the end portion 112E of the second interconnection line 112, the end portion 122E of the second branch portion 122, and the second region therebetween. Here, openings may be formed to expose the first to third substrate pads 125, 124, and 126, respectively.

Referring back to FIG. 3, the connection conductive pattern 160 may be selectively formed in one of the first and second openings OP1 and OP2. The connection conductive pattern 160 may be formed using a direct printing method (e.g., an inkjet printing method).

According to an embodiment of the present disclosure, a connection conductive pattern, which is formed separately from a package substrate, may be used for a mode selection of a control chip, and the mode selection may be possible in a single package substrate, regardless of the number of memory chips. Thus, it may be unnecessary to fabricate an additional package substrate or to change the design of the package substrate, and it may be possible to reduce the process cost. The connection conductive pattern may be formed using a direct printing method, and thus, it may be possible to increase the area efficiency and to reduce the size of the package.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor package, comprising:
a package substrate;
a control chip and a chip stack on the package substrate; and
a connection conductive pattern disposed on a top surface of the package substrate and spaced apart from the control chip in a horizontal direction,
wherein the package substrate comprises:
a first substrate pad;
an extended interconnection line connected to the first substrate pad, the extended interconnection line comprising a first branch portion and a second branch portion;
a first interconnection line spaced apart from the first branch portion in the horizontal direction; and
a second interconnection line spaced apart from the second branch portion in the horizontal direction,
wherein the control chip comprises:
a mode selection pin; and
a chip connection terminal disposed between the first substrate pad and the mode selection pin,
wherein:
the connection conductive pattern is in contact with an end portion of the first branch portion and an end portion of the first interconnection line, and is spaced apart from the second branch portion and the second interconnection line, and
a level of a top surface of the connection conductive pattern is lower than a level of a bottom surface of the control chip.

2. The semiconductor package of claim 1, further comprising a solder resist layer covering a portion of the extended interconnection line, the first interconnection line, and the second interconnection line,
wherein the solder resist layer comprises a first opening and a second opening,
the first opening exposes the end portion of the first branch portion and the end portion of the first interconnection line, and
the second opening exposes an end portion of the second branch portion and an end portion of the second interconnection line.

3. The semiconductor package of claim 2, wherein a distance between the end portion of the first branch portion and the end portion of the first interconnection line is smaller than an exposed length of the end portion of the first branch portion and an exposed length of the end portion of the first interconnection line.

4. The semiconductor package of claim 1, wherein one of the first and second interconnection lines is applied with a power voltage, and another one of the first and second interconnection lines is applied with a ground voltage.

5. The semiconductor package of claim 1, wherein the chip stack is provided in plural, and
the control chip is disposed between a plurality of chip stacks.

6. The semiconductor package of claim 1, wherein the chip stack is disposed on the control chip,
the semiconductor package further comprises a supporting structure disposed between the package substrate and the chip stack, and
the supporting structure is spaced apart from the control chip in the horizontal direction.

7. The semiconductor package of claim 1, wherein each of the extended interconnection line, the first interconnection line, and the second interconnection line comprises a first metal,
the connection conductive pattern comprises a second metal, and
the first metal and the second metal are different from each other.

8. The semiconductor package of claim 7, wherein the first metal is copper, and the second metal is silver.

9. The semiconductor package of claim 1, wherein the package substrate further comprises second substrate pads, which are spaced apart from the first substrate pad in the horizontal direction, and
the chip stack comprises a plurality of memory chips, which are stacked in a cascade structure, and bonding wires, which connect the memory chips to the second substrate pads.

10. A semiconductor package, comprising:
a package substrate; and
a control chip and a chip stack on the package substrate,
wherein the package substrate comprises:
a substrate pad;
an extended interconnection line connected to the substrate pad, the extended interconnection line comprising a first branch portion and a second branch portion;
a first interconnection line spaced apart from the first branch portion in a horizontal direction; and
a second interconnection line spaced apart from the second branch portion in the horizontal direction,
wherein the control chip comprises:
a mode selection pin; and
a chip connection terminal disposed between the substrate pad and the mode selection pin,
wherein:
the semiconductor package further comprises a connection conductive pattern, which is selectively disposed in one of a first region between the first branch portion and the first interconnection line or a second region between the second branch portion and the second interconnection line, and
the first interconnection line, the second interconnection line, the extended interconnection line, and the connection conductive pattern are disposed on a same plane.

11. The semiconductor package of claim 10, wherein the connection conductive pattern is in contact with a top surface of the package substrate in the first region or the second region.

12. The semiconductor package of claim 10, wherein the chip stack comprises a plurality of memory chips, which are stacked in a cascade structure, and metal connection lines, which connect the memory chips to the package substrate, and
the metal connection lines are spaced apart from the extended interconnection line, the first interconnection line, and the second interconnection line.

13. The semiconductor package of claim 10, wherein the control chip is mounted on the package substrate in a flip chip shape.

14. The semiconductor package of claim 10, wherein the first and second interconnection lines are applied with different voltages from each other.

15. The semiconductor package of claim 14, wherein the first interconnection line is applied with a power voltage, and
the second interconnection line is applied with a ground voltage.

16. The semiconductor package of claim 10, wherein the extended interconnection line has a “Y” shape, when viewed in a plan view.

17. The semiconductor package of claim 10, wherein the first and second branch portions have a first width in a first direction parallel to a top surface of the package substrate,
the connection conductive pattern has a second width in the first direction, and
the first width is larger than the second width.

18. The semiconductor package of claim 10, wherein the control chip is overlapped with the substrate pad and is spaced apart from the first and second branch portions, when viewed in a plan view.

19. A semiconductor package, comprising:
a package substrate;
a solder resist layer on the package substrate;
a control chip and a chip stack on the solder resist layer; and
a molding member covering the control chip and the chip stack;
wherein the package substrate comprises:
a substrate pad;
an extended interconnection line connected to the substrate pad, the extended interconnection line comprising a first branch portion and a second branch portion;
a first interconnection line spaced apart from the first branch portion in a horizontal direction; and
a second interconnection line spaced apart from the second branch portion in the horizontal direction,
wherein the control chip comprises:
a mode selection pin; and
a chip connection terminal disposed between the substrate pad and the mode selection pin,
wherein the chip stack comprises:
a plurality of memory chips stacked in a vertical direction; and
connection structures electrically connecting the memory chips to the package substrate,
wherein:
the solder resist layer covers a portion of the extended interconnection line, the first interconnection line, and the second interconnection line,
the solder resist layer comprises a first opening and a second opening,
the first opening exposes an end portion of the first branch portion and an end portion of the first interconnection line,
the second opening exposes an end portion of the second branch portion and an end portion of the second interconnection line,
the semiconductor package further comprises a connection conductive pattern disposed in the first opening,
the connection conductive pattern is in contact with the end portion of the first branch portion and the end portion of the first interconnection line, and is spaced apart from the second branch portion and the second interconnection line,
one of the first and second interconnection lines is applied with a power voltage, and
another one of the first and second interconnection lines is applied with a ground voltage.

20. The semiconductor package of claim 19, wherein the molding member is not interposed between the connection conductive pattern and a top surface of the package substrate.
